(19) United States
(12) Patent Application Publication
(10) Pub. No.: US 2023/0155013 A1
(43) Pub. Date: May 18, 2023

(54) SEMICONDUCTOR DEVICE

(71) Applicant: RENESAS ELECTRONICS CORPORATION, Tokyo (JP)

(72) Inventor: Nao NAGATA, Tokyo (JP)

(21) Appl. No.: 17/529,863

(22) Filed: Nov. 18, 2021

(51) Int. Cl. H01L 29/739; H01L 27/06; H01L 49/02

(52) U.S. Cl. CPC H01L 29/7396; H01L 27/0635; H01L 28/20

(57) ABSTRACT

A semiconductor device includes a semiconductor substrate, a plurality of IGBTs (Insulated Gate Bipolar Transistors) formed on the semiconductor substrate), a gate electrode, a plurality of gate wires coupled to the gates of the IGBTs, and a gate resistor coupled to the gate electrode and the plurality of gate wires, wherein the gate resistor comprises a resistive element, a first contact that couples the gate electrode and the resistive element, and a plurality of second contacts each of which corresponds to each of the plurality of gate wires and couples to the resistive element and the corresponding gate wire, respectively, and wherein each of the plurality of second contacts is formed at a different distance from the first contact.

### BACKGROUND

The present invention relates to a semiconductor device and a manufacturing method thereof, and more particularly, the present invention relates to a semiconductor device including IGBT (Insulated Gate Bipolar Transistor).

Some power modules handling high power, which are configured by connecting a plurality of IGBTs mounting chips in parallel. In this power module, since a plurality of IGBTs operate at the same time, a gate resistor for switching operation stabilize is incorporated.

Patent Document 1 discloses a technique of forming the gate resistor (polysilicon) having a stripe shape. This makes it possible to suppress an increase in the chip area.

### PRIOR-ART DOCUMENT

### Patent Document

[Patent Document 1] Japanese Unexamined Publication Laid-Open No. 2020-92214

### SUMMARY

According to the technique of Patent Document 1, the area of the gate resistance portion can be reduced. Further, by adjusting the stripe shape, it is possible to adjust the gate resistance value of the entire one IGBT chip. However, there is no statement about adjusting the gate-resistance of each of the plurality of IGBTs formed in an IGBT chip.

Generally, an IGBT chip is formed with an emitter pad in an area occupying a large part of its surface, and a gate pad is formed in its surrounding part. It can be said that a plurality of IGBTs is formed in an IGBT chip. The gate of each of the plurality of IGBTs is provided with a gate potential from a gate pad (gate electrode) via a gate resistor and a gate wire. Here, for example, a gate resistance of an IGBT in the vicinity of the gate pad (or, the gate resistor of polysilicon formed as in Patent Document 1) is different from a gate resistance of an IGBT distant from the gate pad, due to a gate wire length difference thereof. That is, the gate resistance of each of the plurality of IGBTs in IGBT chip will vary. Variations in the gate resistance of each of the plurality of IGBTs in IGBT chip results in variations in the switching (turn-on/turn-off) of each of IGBTs. Variation in the switching of the plurality of IGBTs results in lowering a breakdown resistance of IGBT chip and increasing switching loss.

It can be said that the variation of the gate resistor value is proportional to a size of IGBT chip. In IGBT chip for large power (high withstand voltage, large current), since the chip size is increased, the problems described above become more problematic. A solution to this problem is required.

Other objects and novel features will become apparent from the description of the specification and drawings.

The semiconductor device according to an embodiment includes a semiconductor substrate, a plurality of IGBTs (Insulated Gate Bipolar Transistors) formed on the semiconductor substrate), a gate electrode, a plurality of gate wires coupled to the gates of the IGBTs, and a gate resistor coupled to the gate electrode and the plurality of gate wires, wherein the gate resistor comprises a resistive element, a first contact that couples the gate electrode and the resistive element, and a plurality of second contacts each of which corresponds to each of the plurality of gate wires and couples to the resistive element and the corresponding gate wire, respectively, and wherein each of the plurality of second contacts is formed at a different distance from the first contact.

### BRIEF DESCRIPTION OF THE DRAWINGS

FIG. 1 is a plan view of a semiconductor device according to first embodiment.

FIG. 2 is a plan view of the semiconductor device according to the first embodiment.

FIG. 3 is a cross-sectional view of the semiconductor device according to the first embodiment.

FIG. 4 is a cross-sectional view of the semiconductor device according to the first embodiment.

FIG. 5 is a cross-sectional view of the semiconductor device according to the first embodiment.

FIG. 6 is a cross-sectional view of a semiconductor device according to second embodiment.

FIG. 7 is a diagram for explaining the operation of the semiconductor device according to the second embodiment.

FIG. 8 is a plan view of the semiconductor device according to the second embodiment.

FIG. 9 is a cross-sectional view of the semiconductor device according to the second embodiment.

### DETAILED DESCRIPTION

Hereinafter, a semiconductor device according to an embodiment will be described in detail by referring to the drawings. In the specification and the drawings, the same or corresponding form elements are denoted by the same reference numerals, and a repetitive description thereof is omitted. In the drawings, for convenience of description, the configuration may be omitted or simplified. Also, at least some of the embodiments may be arbitrarily combined with each other.

### First Embodiment

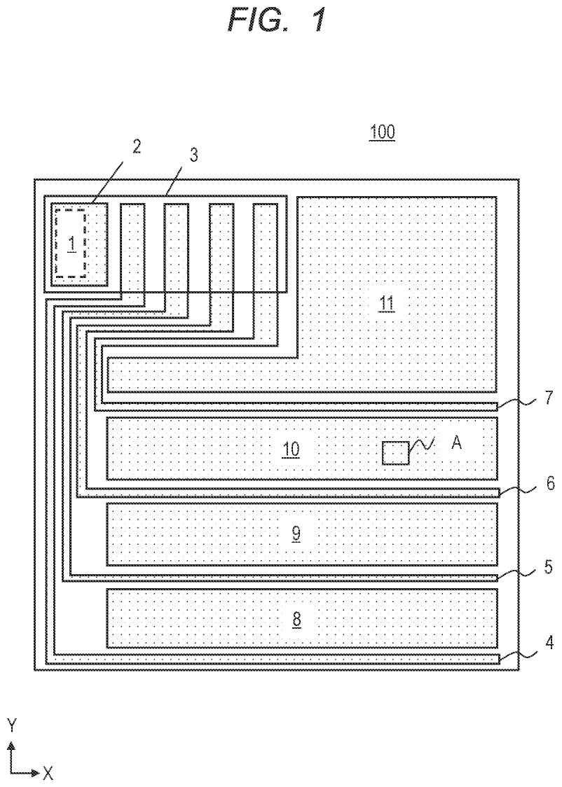

FIG. 1 is a plan view of a semiconductor (IGBT) chip 100 (semiconductor device) according to the first embodiment. In FIG. 1, an insulating film is made transparent for simplicity of understanding. As shown in FIG. 1, most of the surface of the semiconductor chip 100 is covered with emitter pads 8-11 (the portion of the emitter electrode that is not covered by the protective film). Gate pad 1 and the gate electrode 2 are formed on the left corner of the semiconductor chip 100. Further, the collector electrode 12 is formed on the back surface of the semiconductor chip 100. The gate pad 1 is supplied with a gate potential, and the emitter pads 8-11 are supplied with an emitter potential. The gate wires 4-7 are coupled to the gate electrode 2 (gate pad 1) via the gate resistor 3.

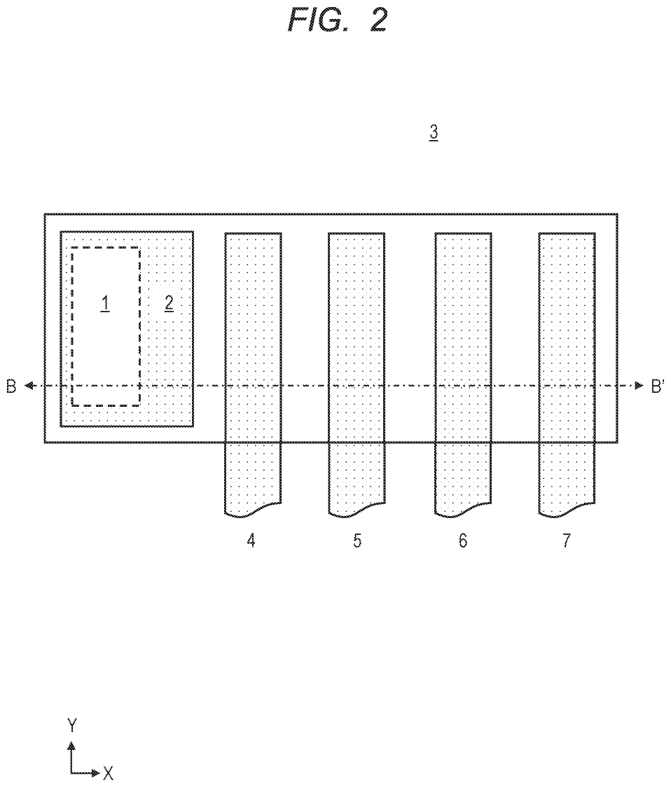

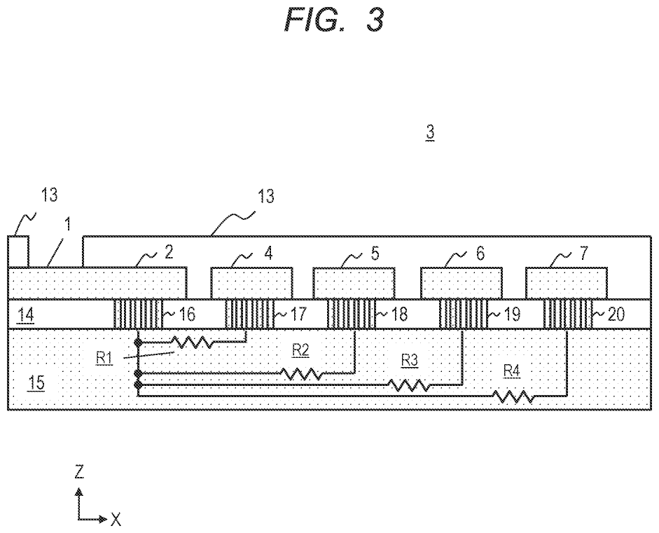

FIG. 2 is an enlarged view of the gate resistor 3. Further, FIG. 3 is a cross-sectional view taken along B-B′ of FIG. 2. As shown in FIG. 3, the gate resistor 3 is composed of a gate electrode 2, a resistor element 15 formed under the gate wires 4-7, and contacts 16-20. The gate electrode 2 and the gate wires 4 to 7 are formed of, for example, aluminum (Al). The resistive element 15 is made of polysilicon (Poly-Si), for example. Incidentally, 13 is a protective film, 14 is an interlayer isolated film (SiO₂).

Contact 16 (first contact) connects the gate electrode 2 and the resistor element 15. The contacts 17-20 (second contacts) connect the gate wires 4-7 and the resistive element 15, respectively. Here, the resistance values contributing to the gate wires 4 to 7 are R1 to R4, respectively, by the resistor element 15. As apparent from FIG. 3, depending on the distance from the gate electrode 2, R1<R2<R3<R4.

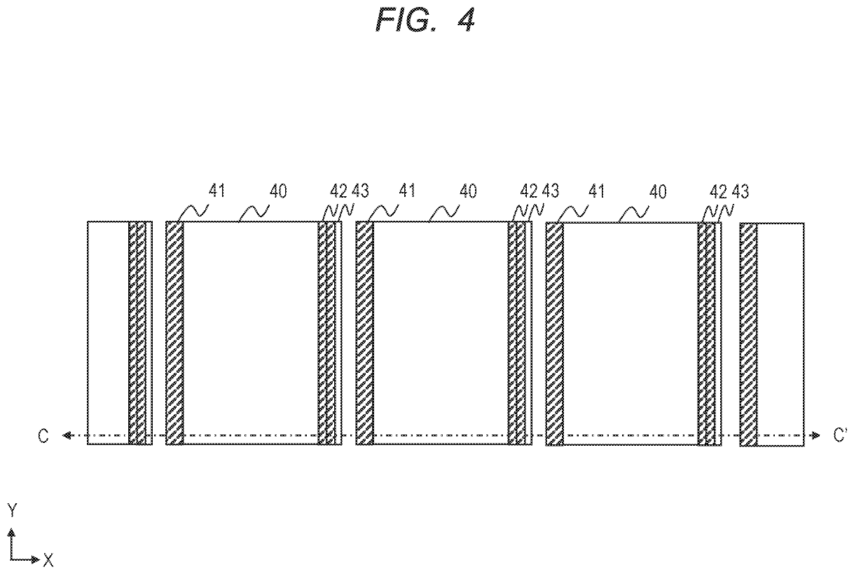

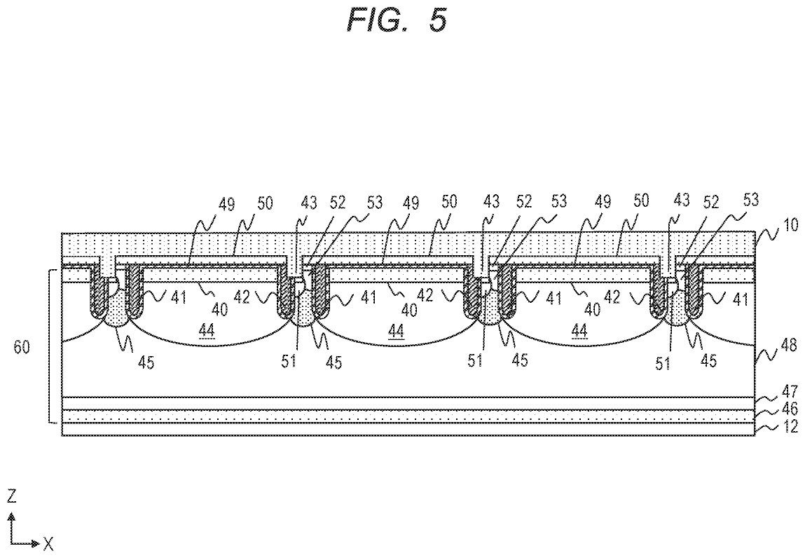

Next, an IGBT formed on the semiconductor chip 100 will be described with reference to FIGS. 4 and 5. FIG. 4 is an enlarged view of the region A of FIG. 1. FIG. 5 is a cross-sectional view taken along C-C′ line of FIG. 4. FIGS. 4 and 5 illustrate an exemplary IGBT formed in the semiconductor chip 100. Here, IGBT of GE-S type (GE type shrink structure) which is a kind of IGBT of the IE type is shown.

As shown in FIGS. 4 and 5, the semiconductor chip 100, the semiconductor substrate 60, the emitter electrode 10, the collector electrode 12, p+ type collector layer 46, n+ type field stop layer 47, n− type drift layer 48 are formed. The semiconductor chip 100 further includes a gate potential trench electrode 41 (also referred to as a trench gate of the gate potential) to which the gate potential is supplied, an emitter potential trench electrode 42 (also referred to as a trench gate of the emitter potential) to which the emitter potential is supplied. Between the gate potential trench electrode 41 and the emitter potential trench electrode 42, a hole barrier layer 45 of high concentration n+ type is formed. Gate potential trench electrode 41, the emitter potential trench electrode 42, the region formed by the hole barrier layer 45 are an active cell region. A p type floating layer 44 and a p type body layer 40 are formed between the two active cell regions.

The emitter potential trench electrode 42, the emitter electrode 10 are coupled via a contact 43. The emitter electrode 10 is coupled to the p+ type body layer 51 via the contact 43 and body contact. Between the gate potential trench electrode 41 and the contact 43 of the emitter electrode 10, n+ type emitter layer 52, p+ type base layer 53 are formed. Incidentally, 49 in FIG. 5 is a gate insulating film, 50 is an interlayer insulating film.

IGBT described above is formed below the emitter electrodes 8,9,10,11.

Returning again to FIG. 1, the semiconductor chip 100 of the first embodiment will be described. The gate wire 4 is coupled to the gate potential trench electrode 41 of IGBT formed below the emitter electrode 8. The gate wire 5 is coupled to the gate potential trench electrode 41 of IGBT formed below the emitter electrode 9. The gate wire 6 is coupled to the gate potential trench electrode 41 of IGBT formed below the emitter electrode 10. The gate wire 7 is coupled to the gate potential trench electrode 41 of IGBT formed below the emitter electrode 11.

As is apparent from FIG. 1, in the order of the emitter electrodes 8, 9, 10, 11, the distance from the gate pad 1 is far. Then, the wiring length is long in the order of the gate wiring 4, 5, 6, 7. In other words, the resistance value of each gate wiring: gate wiring 4>gate wiring 5>gate wiring 6>gate wiring 7. Between each gate wiring and the gate pad 1 (gate electrode 2), the gate resistor 3 described above is connected. That is, the gate resistances of IGBTs formed below the emitter electrodes 8 to 11 become a resistance value of the gate wiring 4 +R1, a resistance value of the gate wiring 5 +R2, a resistance value of the gate wiring 6 +R3, and a resistance value of the gate wiring 7 +R4, respectively. As described above, since R1<R2<R3<R4, by adjusting the gate resistor 3 at the time of manufacture, it becomes possible to make: the resistance value of the gate wiring 4 +R1≈(substantially equal to) the resistance value of the gate wiring 5 +R2≈the resistance value of the gate wiring 6 +R3 the resistance value of the gate wiring 7 +R4.

As described above, in IGBT chip 100 according to the first embodiment, each of gate wires is coupled to each of the gate resistors having different resistances, respectively. Thus, it is possible to suppress variations in IGBT operation in the chip due to variations in the gate wiring length.

Although the first embodiment has been described as a GE-S type IGBT, the present invention is not limited to this. Other types of IGBT, e.g., GG, EGE, GGEE, etc., or planar gate IGBT without trench gates, may be used.

### Second Embodiment

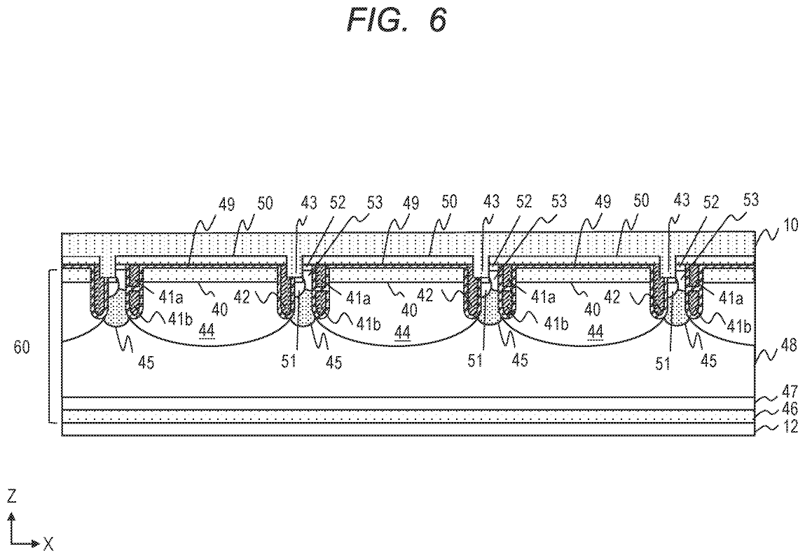

FIG. 6 is a diagram showing a configuration of a IGBT according to second embodiment. Like the first embodiment, FIG. 6 is a cross-sectional view taken along C-C′ line of FIG. 4. The difference from the first embodiment is a gate potential trench electrode. Gate potential trench electrode 41 of the first embodiment corresponds to two gate potential trench electrodes 41a and 41b in the second embodiment.

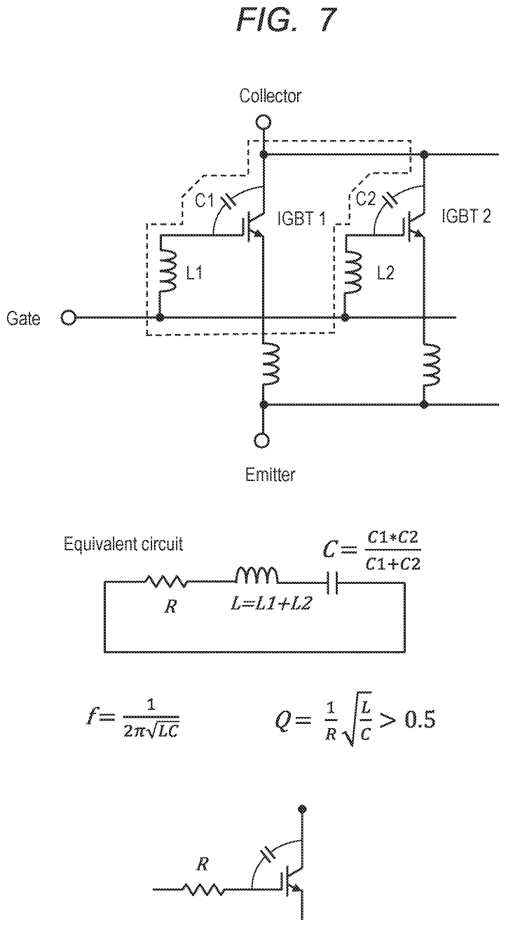

With reference to FIG. 7, the meaning of the two gate potential trench electrodes 41a, 41b will be described. FIG. 7 is a diagram for explaining resonant phenomena that occur when a plurality of IGBTs is connected in parallel. As shown in FIG. 7, when a plurality of (two in FIG. 7) IGBTs is connected in parallel, a loop circuit (broken line) is formed by the parasitic capacitances (C1, C2). The loop circuit also includes parasitic inductances (L1, L2). When the loop circuit is formed by the parasitic capacitance and the parasitic inductance, a resonant phenomenon appears. The lower figure of FIG. 7 is an equivalent circuit when the damping resistor R for suppressing the resonance phenomenon is inserted into the loop circuit. Resonance frequency f and the resonance condition Q in the equivalent circuit is as shown in FIG. 7.

Since the operation of the semiconductor device (IGBT chip) 100 becomes unstable when the resonance phenomenon occurs, it is desirable to suppress the resonance phenomenon. Referring to the resonance condition Q, it can be seen that the resonance phenomenon can be suppressed by increasing the damping resistor R. For IGBT, since the gate resistor functions as the damping resistor R, it is possible to suppress the resonant phenomena by increasing the gate resistor. However, simply increasing the gate resistor slows down the switching operation of IGBT. In other words, it is necessary to determine the gate resistance in consideration of both suppression of the resonance phenomenon and reduction of the switching loss. Therefore, in the second embodiment, to solve this problem by dividing the gate potential trench electrode into two gate potential trench electrodes.

In the second embodiment, IGBT has two gate-potential trench electrodes 41a and 41b. Since the gate potential trench electrode 41a on the upper side has a larger contribution to the switching operation of IGBT as compared with the gate potential trench electrode 41b, a small gate resistor is coupled to the gate potential trench electrode 41a. Since the gate potential trench electrode 41b has a larger contribution as a damping resistor, a large gate resistor is coupled to the gate potential trench electrode 41b. In this way, it is possible to achieve both suppression of the resonance phenomenon and reduction of the switching loss.

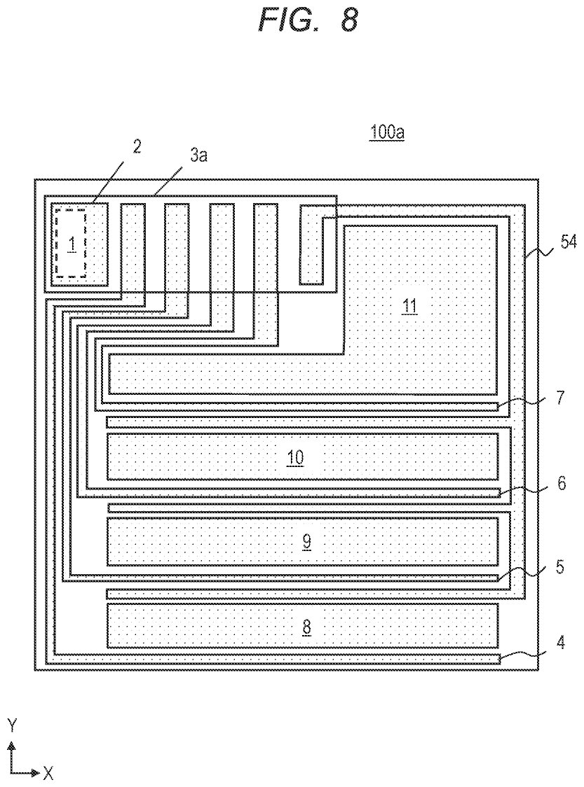

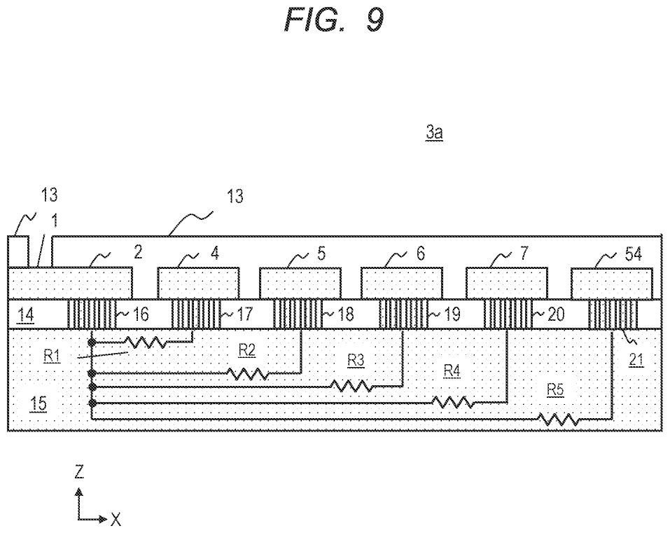

The gate resistors coupled to the gate potential trench electrodes 41a and 41b can be realized by utilizing the same structure as the gate resistor 3 described in the first embodiment. FIGS. 8 and 9 are examples. In the gate resistor 3a, in addition to the structure of FIG. 1, a resistor R5 having a larger resistance value than the resistor R4 is further provided. Resistor R5 is coupled to the gate pad 1 (gate electrode 2) and the gate wiring 54. The gate wiring 54 is coupled to the gate potential trench electrodes 41a of IGBTs formed beneath the emitter pads 8-11. Gate resistors and the gate wirings coupled to the gate potential trench electrode 41b are the same structures as the gate potential trench electrode 41 of the first embodiment.

If the variation of the gate resistors of the gate potential trench electrodes 41a is a problem, as in the first embodiment, by providing a plurality of resistors R5 and a plurality of the gate wirings 54 in accordance with the distance from the gate pad 1, it is possible to suppress the variation of the gate resistance.

Incidentally, the second embodiment is effective as a countermeasure for the resonance phenomenon, and has other effects. In the trench gate type IGBT, the defect phenomena in which hot holes are injected into the trench gate have been confirmed. When IGBT turns off, a dynamic avalanche occurs near the trench gate bottom and Vce becomes high voltage (resulting in hot holes). When the turn-off is completed in this state and the voltage of the trench gate becomes negative, hot holes generated near the trench gate bottom is injected into the trench gate. In the second embodiment, as compared with the gate potential trench electrode 41a, the gate resistance of the gate potential trench electrode 41b (trench gate bottom) is larger. That is, it is possible to shift the operation timings of the gate potential trench electrodes 41a and 41b (the operation of the gate potential trench electrode 41b becomes slower). Since the timing of occurrence of hot holes and the timing of the voltage of the trench gate bottom to be negative can be shifted, it is possible to suppress the above-described defect phenomenon.

As described above, in the semiconductor chip 100a according to the second embodiment, the plurality of gate wirings is coupled to IGBT gates and the gate resistors having different resistance values are coupled to the gate wirings, respectively. Further, the gate potential trench electrode of IGBT is divided into the two gate potential trench electrodes, and the gate resistors having different resistances are coupled to the two gate potential trench electrodes. Thus, in addition to the effect of the first embodiment, it is possible to achieve both suppression of the resonance phenomenon and reduction of the switching loss. Furthermore, it is possible to suppress the failure of hot hole injection into the trench gate.

Although the second embodiment has been described as a GE-S type IGBT, the present invention is not limited to this. Other types of IGBT having trench gates may be used.

It should be noted that the present invention is not limited to the above-mentioned embodiments, and various modifications can be made without departing from the gist thereof.

What is claimed is:

1. A semiconductor device comprising:
a semiconductor substrate;
a plurality of IGBTs (Insulated Gate Bipolar Transistors) formed on the semiconductor substrate);
a gate electrode;
a plurality of gate wires coupled to the gates of the IGBTs; and
a gate resistor coupled to the gate electrode and the plurality of gate wires,
wherein the gate resistor comprises:
a resistive element;
a first contact that couples the gate electrode and the resistive element; and
a plurality of second contacts each of which corresponds to each of the plurality of gate wires and couples to the resistive element and the corresponding gate wire, respectively, and
wherein each of the plurality of second contacts is formed at a different distance from the first contact.

2. The semiconductor device according to claim 1,
wherein the plurality of gate wires include:
a first gate wiring; and
a second gate wiring longer than the first gate wiring,
wherein the plurality of second contacts include:
a third contact coupled to the first gate wiring; and
a fourth contact coupled to the second gate wiring,
wherein a distance between the first contact and the third contact is greater than a distance between the first contact and the fourth contact.

3. The semiconductor device according to claim 2,
wherein the semiconductor substrate has a first and second regions when viewed from the surface,
wherein the plurality of IGBTs is an IGBT formed in each of the first and second regions,
wherein the first gate wire is coupled to the gate of IGBT formed in the first region, and
wherein the second gate wire is coupled to the gate of IGBT formed in the second region.

4. The semiconductor device according to claim 3,
wherein a distance between the first region and the gate electrode is shorter than a distance between the second region and the gate electrode.

5. The semiconductor device according to claim 1, wherein the resistive element comprises a polysilicon.

6. The semiconductor device according to claim 1, wherein the gates of the plurality of IGBTs are trench gates.

7. The semiconductor device according to claim 6,
wherein each of the trench gates includes first and second trench gates,
wherein the first trench gate is formed on the surface side of the semiconductor substrate than the second trench gate, and the second trench gate is formed on the lower side of the first trench gate,
wherein the plurality of gate wires include:
a first gate wiring coupled to the first trench gate; and
a second gate wiring coupled to the second trench gate,
wherein the plurality of second contacts include:
a third contact coupled to the first gate wiring; and
a fourth contact coupled to the second gate wiring,
wherein a distance between the first contact and the third contact is less than a distance between the first contact and the fourth contact.

8. The semiconductor device according to claim 7,
wherein the first gate wiring includes:
a third gate wiring coupled to the first trench gate of a first IGBT among the plurality of IGBTs; and
a fourth gate wiring coupled to the first trench gate of a second IGBT among the plurality of IGBTs, the fourth gate wiring being longer than the third gate wiring,
wherein the third contact includes:
a fifth contact coupled to the third gate wiring; and
a sixth contact coupled to the fourth gate wiring,
wherein a distance between the first contact and the fifth contact is greater than a distance between the first contact and the sixth contact.

9. The semiconductor device according to claim 8,
wherein the semiconductor substrate has a first and second regions when viewed from the surface,
wherein the first IGBT is formed in the first region and the second IGBT is formed in the second region.

10. The semiconductor device according to claim 9,
wherein a distance between the first region and the gate electrode is shorter than a distance between the second region and the gate electrode.
